(19) United States
(12) Patent Application Publication
(10) Pub. No.: US 2025/0054846 A1
(43) Pub. Date: Feb. 13, 2025

(54) SEMICONDUCTOR PACKAGE

(71) Applicant: Samsung Electronics Co., Ltd., Suwon-si (KR)

(72) Inventors: Jaesun Kim, Suwon-si (KR); Kwangsoo Kim, Suwon-si (KR); Yiseul Han, Suwon-si (KR)

(21) Appl. No.: 18/633,688

(22) Filed: Apr. 12, 2024

(30) Foreign Application Priority Data
Aug. 11, 2023 (KR) 10-2023-0105672

(51) Int. Cl. H01L 23/498; H01L 23/00; H01L 23/31; H01L 23/538; H01L 25/065; H10B 80/00

(52) U.S. Cl. CPC H01L 23/49811; H01L 23/3128; H01L 23/5383; H01L 23/5385; H01L 25/0652; H10B 80/00; H01L 24/16; H01L 2224/16227

(57) ABSTRACT

Provided is a semiconductor package having a multi-chip package structure including a lower semiconductor chip and an upper semiconductor chip. The upper semiconductor chip includes a plurality of upper semiconductor chips, and one of the plurality of upper semiconductor chips is integrally connected to an adjacent one of the plurality of upper semiconductor chips with a scribe lane therebetween on a same plane.

### CROSS-REFERENCE TO RELATED APPLICATION

This application is based on and claims priority under 35 U.S.C. § 119 to Korean Patent Application No. 10-2023-0105672, filed on Aug. 11, 2023, in the Korean Intellectual Property Office, the disclosure of which is incorporated by reference herein in its entirety.

### BACKGROUND

The inventive concepts relate to a semiconductor package. More particularly, the inventive concepts relate to a fan out wafer level package (FOWLP).

Recently, demand for portable devices in the electronic products market has rapidly increased, and according to this, electronic components mounted in these electronic products have been continuously demanded to be small and light. To make electronic components small and light, semiconductor packages mounted in the electronic components have been demanded to process high-capacity data with a small volume. High integration and single packaging of semiconductor chips mounted in the semiconductor packages have been demanded. Accordingly, a semiconductor package having a stack structure to efficiently arrange semiconductor chips in a limited structure of the semiconductor package has been used.

### SUMMARY

The inventive concepts provide a semiconductor package with an improved strength of the whole structure of the semiconductor package by reinforcing the strength between upper chips mounted in the semiconductor package.

In addition, the problem to be solved by the technical idea of the inventive concepts is not limited to the problem mentioned above, and other problems will be more clearly understood by those of ordinary skill in the art from the description below.

The inventive concepts provide semiconductor packages below to achieve the technical problems.

According to aspects of the inventive concepts, there is provided a semiconductor package including a base substrate having a lower redistribution layer, a lower semiconductor chip including a plurality of lower semiconductor chips having a first active surface and first connection pads on the first active surface, wherein the plurality of lower semiconductor chips are on the base substrate such that the first active surface faces an upper surface of the base substrate, and wherein each of the first connection pads is electrically connected to the lower redistribution layer, an upper semiconductor chip having a second active surface and second connection pads on the second active surface, wherein the upper semiconductor chip is on the lower semiconductor chip such that the second active surface faces the lower semiconductor chip, an intermediate connection member on the second active surface of the upper semiconductor chip and between the lower semiconductor chip and the upper semiconductor chip, the intermediate connection member having an upper redistribution layer electrically connected to each of the second connection pads, a plurality of vertical interconnectors at least partially around the lower semiconductor chip on the base substrate and electrically connecting the lower redistribution layer to the upper redistribution layer, and a mold portion on the base substrate and having a first portion at least partially surrounding the lower semiconductor chip and the plurality of vertical interconnectors and a second portion extending on the upper redistribution layer and side surfaces of the upper semiconductor chip, wherein the upper semiconductor chip includes a plurality of upper semiconductor chips, and one of the plurality of upper semiconductor chips is integrally connected to an adjacent one of the plurality of upper semiconductor chips with a scribe lane therebetween on a same plane.

According to aspects of the inventive concepts, there is provided a semiconductor package including a plurality of first semiconductor chips having a first surface, first connection pads on the first surface, and a second surface opposite to the first surface, a first connection member on the first surface of at least one of the plurality of first semiconductor chips and having a first redistribution layer electrically connected to the first connection pads, a plurality of second semiconductor chips having a third surface and second connection pads on the third surface, a second connection member on the third surface of at least one of the plurality of second semiconductor chips and having a second redistribution layer electrically connected to the second connection pads, a plurality of vertical interconnectors on the second connection member, at least partially around the plurality of second semiconductor chips, and electrically connecting the first redistribution layer to the second redistribution layer, a mold portion on the second connection member, at least partially surrounding the plurality of second semiconductor chips and the plurality of vertical interconnectors, and extending on the first connection member and side surfaces of the plurality of first semiconductor chips, and a scribe lane between ones of the plurality of first semiconductor chips.

According to aspects of the inventive concepts, there is provided a semiconductor package including a base substrate having a lower redistribution layer, a plurality of lower semiconductor chips having a first active surface, first connection pads on the first active surface, and a first inactive surface opposite to the first active surface, wherein the plurality of lower semiconductor chips are separated from each other and are on the base substrate such that the first active surface faces the base substrate, a plurality of upper semiconductor chips having a second active surface, second connection pads on the second active surface, and a second inactive surface opposite to the second active surface, wherein the plurality of upper semiconductor chips have a greater area than the plurality of lower semiconductor chips and are on the plurality of lower semiconductor chips such that the second active surface faces at least one of the plurality of lower semiconductor chips, and wherein ones of the plurality of upper semiconductor chips are on a same plane with a scribe lane therebetween, an intermediate connection member on the second active surface of at least one of the plurality of upper semiconductor chips and between the at least one of the plurality of lower semiconductor chips and the at least one of the plurality of upper semiconductor chips, the intermediate connection member having an upper redistribution layer electrically connected to each of the second connection pads, a plurality of first vertical interconnectors at least partially around the plurality of lower semiconductor chips on the base substrate and electrically connecting the lower redistribution layer to the upper redistribution layer, a plurality of second vertical interconnectors between ones of the plurality of lower semiconductor chips, below the plurality of upper semiconductor chips, and electrically connecting the upper redistribution layer to the lower redistribution layer, and a mold portion on the base substrate, at least partially surrounding the lower semiconductor chip and the plurality of first and second vertical interconnectors, and extending on the upper redistribution layer and side surfaces of the plurality of upper semiconductor chips, wherein a height from an upper surface of the base substrate to an uppermost surface of the mold portion is greater than a height from the upper surface of the base substrate to the second inactive surface of the at least one of the plurality of upper semiconductor chips.

### BRIEF DESCRIPTION OF THE DRAWINGS

Embodiments of the inventive concepts will be more clearly understood from the following detailed description taken in conjunction with the accompanying drawings in which:

FIG. 1 is a side cross-sectional view of a semiconductor package according to some embodiments;

FIG. 2 is a top view of the semiconductor package shown in FIG. 1;

FIGS. 3A and 3B are partial magnified views of portions A and B of the semiconductor package shown in FIG. 1, respectively;

FIG. 4 is a partial magnified view of a semiconductor package according to some embodiments;

FIG. 5 is a side cross-sectional view of a semiconductor package according to some embodiments;

FIGS. 6A to 6D are cross-sectional views of main processes to describe some processes of a method of manufacturing a semiconductor package, according to some embodiments; and

FIGS. 7A to 7D are cross-sectional views of main processes to describe some processes of a method of manufacturing a semiconductor package, according to some embodiments.

### DETAILED DESCRIPTION

Hereinafter, example embodiments are described in detail with reference to the accompanying drawings. Like reference numerals in the drawings denote like elements, and thus their repetitive description will be omitted.

The embodiments may allow various kinds of change or modification and various changes in form, and specific embodiments will be illustrated in the drawings and described in detail in the specification. However, it should be understood that the specific embodiments do not limit the scope to a specific disclosing form but include every modified, equivalent, or replaced one within the disclosed technical scope. In the description of the embodiments, when it is determined that a specific description of relevant well-known features may obscure the essentials of the embodiments, a detailed description thereof is omitted.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. It will be understood that, although the terms first, second, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure.

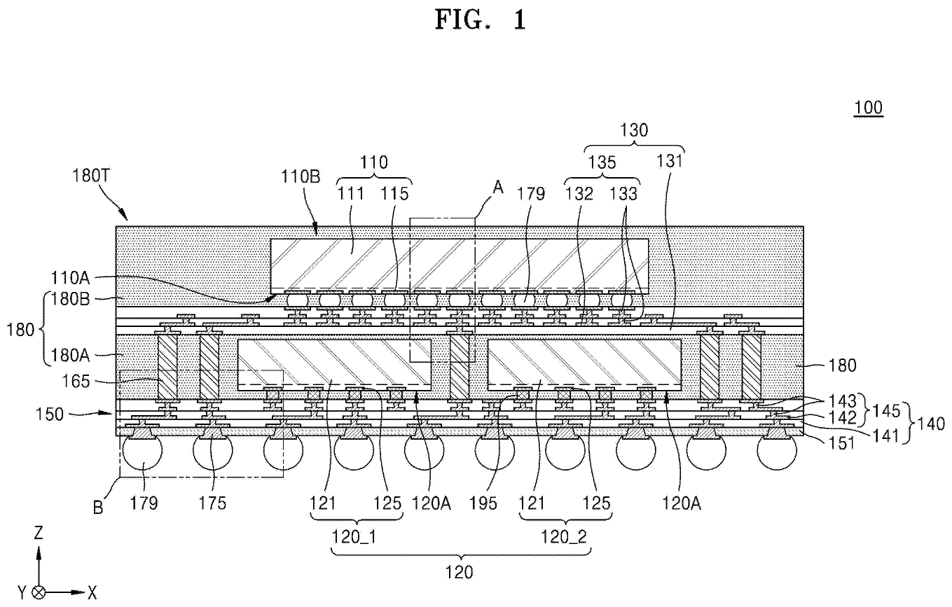

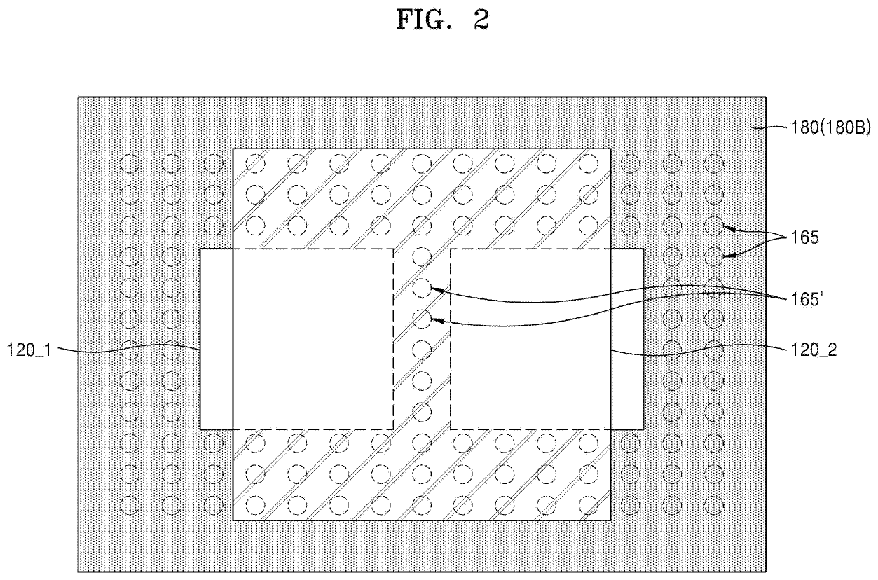

FIG. 1 is a side cross-sectional view of a semiconductor package 100 according to some embodiments, and FIG. 2 is a top view of the semiconductor package 100 shown in FIG. 1.

Referring to FIGS. 1 and 2, the semiconductor package 100 according to some embodiments may include a base substrate 150, a lower semiconductor chip 120 on the base substrate 150, an upper semiconductor chip 110 on the lower semiconductor chip 120, and a mold portion 180 on the base substrate 150 and surrounding the lower semiconductor chip 120 and the upper semiconductor chip 110. It will be understood that “an element A surrounds an element B” (or similar language) as used herein means that the element A is at least partially around the element B but does not necessarily mean that the element A completely encloses the element B.

The upper semiconductor chip (also referred to as a “first semiconductor chip”) 110 may have an active surface 110A on which connection pads 115 are disposed and an inactive surface 110B opposite to the active surface 110A. The upper semiconductor chip 110 may be on the lower semiconductor chip 120 such that the active surface 110A faces the lower semiconductor chip 120. In some embodiments, one semiconductor chip included in the upper semiconductor chip 110 may have the same area as one of first and second lower semiconductor chips 120_1 and 120_2 included in the lower semiconductor chip 120. In some embodiments, the one semiconductor chip included in the upper semiconductor chip 110 may have a different area and the like from those of the first and second lower semiconductor chips 120_1 and 120_2.

In some embodiments, the upper semiconductor chip 110 includes a plurality of upper semiconductor chips, and one of the plurality of upper semiconductor chips may be integrally connected to an adjacent one of the plurality of upper semiconductor chips with a scribe lane therebetween on a same plane. In other words, ones of the plurality of upper semiconductor chips included in the upper semiconductor chip 110 may be on a same plane with a scribe lane therebetween, and the ones of the plurality of upper semiconductor chips may be at opposing sides of the scribe lane and integrally connected on the same plane. For example, as shown in FIG. 1, one of the plurality of upper semiconductor chips included in the upper semiconductor chip 110 may be integrally connected to an adjacent one of the plurality of upper semiconductor chips on a same plane, and the first and second lower semiconductor chips 120_1 and 120_2 included in the lower semiconductor chip 120 may be separated from each other. As used herein, “an element A integrally connected to an element B” (or similar language) means that the element A and the element B may be viewed as a single monolithic structure. In some embodiments, a horizontal distance between the first and second lower semiconductor chips 120_1 and 120_2 may be different from a horizontal distance between ones of the plurality of upper semiconductor chips included in the upper semiconductor chip 110.

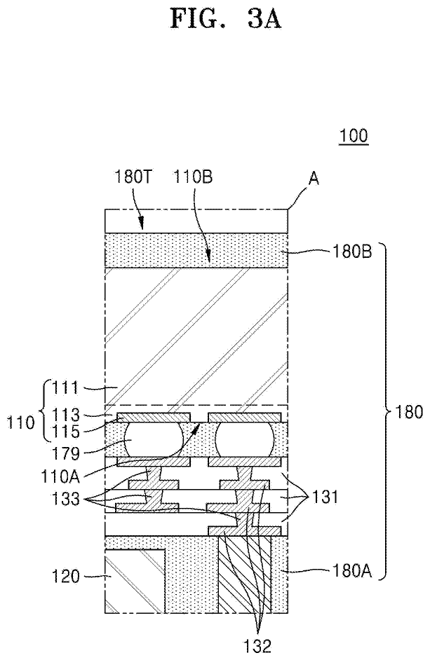

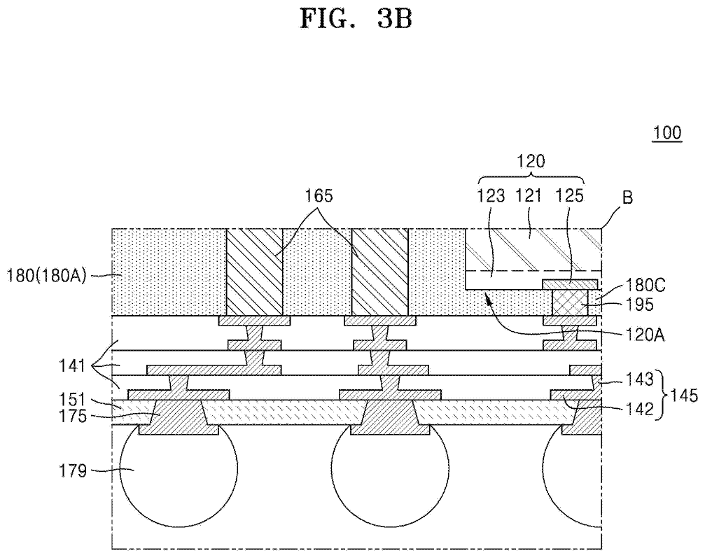

FIG. 3A is a partial magnified view of portion A of the semiconductor package 100 shown in FIG. 1.

Referring to FIGS. 1 and 3A, a first connection member (also referred to as an “intermediate connection member”) 130 may be on the active surface 110A of the upper semiconductor chip 110. The active surface 110A of the upper semiconductor chip 110 may face the first connection member 130. The first connection member 130 may include a plurality of insulating layers 131 and an upper redistribution layer (also referred to as a “first redistribution layer”) 135 formed in the plurality of insulating layers 131. The upper redistribution layer 135 may include a redistribution pattern 132 in each of the plurality of insulating layers 131 and a plurality of vias 133 each connecting adjacent redistribution patterns 132 to each other by penetrating (i.e., extending into) a corresponding insulating layer 131. Some of the plurality of vias 133 may be directly connected to the connection pads 115. That is, in some embodiments, the upper semiconductor chip 110 may be directly connected to the upper redistribution layer 135 through a via 133 of the upper redistribution layer 135 by an external connection metal 179. Each of the plurality of vias 133 may have a width increasing toward the active surface 110A of the upper semiconductor chip 110. For example, each of the plurality of vias 133 may have a width in a first direction X and/or a second direction Y that increases toward the active surface 110A of the upper semiconductor chip 110. The first direction X and the second direction Y may intersect each other and may be parallel to an upper surface of the base substrate 150. The first direction X and the second direction Y may intersect a third direction Z, and the third direction Z may be perpendicular to the upper surface of the base substrate 150.

The first connection member 130 may have an area corresponding to the active surface 110A of the upper semiconductor chip 110 (see FIG. 1). In some embodiments, the first connection member 130 may have a flat side surface substantially coplanar with a side surface of the upper semiconductor chip 110.

As shown in FIG. 1, the first connection member 130 may be between the lower semiconductor chip 120 and the upper semiconductor chip 110. The lower semiconductor chip 120 may be on one region of the first connection member 130.

The lower semiconductor chip (also referred to as a “second semiconductor chip”) 120 may have an active surface 120A on which connection pads 125 are disposed and an inactive surface opposite to the active surface 120A.

The lower semiconductor chip 120 may be on one region of the base substrate 150 such that the active surface 120A of the lower semiconductor chip 120 faces the upper surface of the base substrate 150. The base substrate 150 may include a second connection member 140 having a lower redistribution layer (also referred to as a “second redistribution layer”) 145. Each of the connection pads 125 of the lower semiconductor chip 120 may be connected to the lower redistribution layer 145. As used herein, “an element A connected to an element B” (or similar language) means that the element A is physically and/or electrically connected to the element B.

Although it is shown that the lower semiconductor chip 120 includes the first and second lower semiconductor chips 120_1 and 120_2, this is only illustrative, and the inventive concepts are not limited thereto. In some embodiments, the lower semiconductor chip 120 may include three or more semiconductor chips.

FIG. 3B is a partial magnified view of portion B of the semiconductor package 100 shown in FIG. 1.

Referring to FIGS. 1 and 3B, like the first connection member 130, the second connection member 140 may include a plurality of insulating layers 141, and like the upper redistribution layer 135, the lower redistribution layer 145 may include a redistribution pattern 142 in each of the plurality of insulating layers 141 and a plurality of vias 143 each connecting adjacent redistribution patterns 142 to each other by penetrating (i.e., extending into) a corresponding insulating layer 141. Some of the plurality of vias 143 may be connected to the connection pads 125. Each of the plurality of vias 143 may have a width increasing toward the active surface 120A of the lower semiconductor chip 120.

Although it is illustrated that each of the first and second connection members 130 and 140 includes three insulating layers 131 or 141 and three upper or lower redistribution layers 135 or 145, in some other embodiments, each of the first and second connection members 130 and 140 may include one or more layers, and the first and second connection members 130 and 140 may include different numbers of redistribution layers. The insulating layers 131 and 141 may include a photosensitive insulating material, such as a photo-imageable dielectric (PID) resin. Even though the insulating layers 131 and 141 each include multiple layers, the boundary between layers may not be clear according to the material of each of the insulating layers 131 and 141 and a process of forming the insulating layers 131 and 141. For example, the upper and lower redistribution layers 135 or 145 may include a conductive material, such as copper (Cu), aluminum (Al), silver (Ag), tin (Sn), gold (Au), nickel (Ni), lead (Pb), titanium (Ti), or an alloy thereof. When the upper and lower redistribution layers 135 or 145 are formed, vias 133 and 143 may be formed to be respectively integrated with the upper and lower redistribution layers 135 or 145 through the same process (e.g., a plating process).

In some embodiments, the base substrate 150 and/or the second connection member 140 may have a greater area than the first connection member 130. In some embodiments, the base substrate 150 may include a passivation layer 151 on the second connection member 140 and having openings and an under bump metallurgy (UBM) layer 175 connected to the lower redistribution layer 145 through each opening of the passivation layer 151. For example, the UBM layer 175 may be formed in each opening of the passivation layer 151 by metallization but is not limited thereto. The external connection metal 179 may physically and/or electrically connect the semiconductor package 100 to an external device, such as a mainboard of an electronic device. The external connection metal 179 may include a low melting point metal, e.g., Sn—Al—Cu solder or the like. The external connection metal 179 may include layers or a single layer. For example, the layers may include a Cu pillar and a solder, and the single layer may include Sn—Ag solder or Cu.

A plurality of vertical interconnectors 165 connecting the lower redistribution layer 145 to the upper redistribution layer 135 may be on the base substrate 150.

As shown in FIG. 2, a plurality of vertical interconnectors 165 and 165′ may be arranged around the first and second lower semiconductor chips 120_1 and 120_2 in a plurality of columns. Although it is illustrated that the plurality of vertical interconnectors 165 are arranged in one column or two columns along each side of the first and second lower semiconductor chips 120_1 and 120_2, in some other embodiments, the plurality of vertical interconnectors 165 may be arranged along only some sides (e.g., both sides facing each other) or arranged in a different number of columns. The plurality of vertical interconnectors 165 and 165′ may have various arrangements. According to the inventive concepts, vertical interconnectors 165′ may be arranged in one or more columns in a space between the first and second lower semiconductor chips 120_1 and 120_2. As a result, a path through which power is supplied to the upper semiconductor chip 110 may be effectively reduced. In some embodiments, the plurality of vertical interconnectors 165 and 165′ may include a metal post (e.g., Cu) and be formed in a plating process.

The semiconductor package 100 may include a mold portion 180 on the base substrate 150 and surrounding the lower semiconductor chip 120 and the plurality of vertical interconnectors 165. The mold portion 180 may extend on the side surfaces of the upper semiconductor chip 110 and the external connection metal 179.

As shown in FIG. 1, the mold portion 180 according to some embodiments may include a first portion 180A surrounding the lower semiconductor chip 120 and the plurality of vertical interconnectors 165 and a second portion 180B extending on the side surfaces of the upper semiconductor chip 110 and the upper redistribution layer 135. In some embodiments, the second portion 180B of the mold portion 180 may be formed to completely surround the side surfaces of the upper semiconductor chip 110 and the upper redistribution layer 135. The second portion 180B of the mold portion 180 may protect the upper semiconductor chip 110 and the upper redistribution layer 135 while guaranteeing solid bonding with the upper semiconductor chip 110. The mold portion 180 may include a curable resin or PID. The mold portion 180 may include, for example, an epoxy mold compound (EMC).

The inactive surface 110B of the upper semiconductor chip 110 may be a substantially flat surface. In addition, the mold portion 180 may have side surfaces substantially flat and coplanar with the side surfaces of the base substrate 150, i.e., coplanar with the side surfaces of the second connection member 140.

In some embodiments, the mold portion 180 may have a portion 180C covering the active surface 120A of the lower semiconductor chip 120 (e.g., see FIG. 3B). A plurality of conductive posts 195 penetrating (i.e., extending into) the covering portion 180C of the mold portion 180 may be on the connection pads 125, respectively. Referring to FIG. 3B, the connection pads 125 of the lower semiconductor chip 120 may be connected to the lower redistribution layer 145 through the plurality of conductive posts 195, respectively. Some vias 143 of the lower redistribution layer 145 may be directly connected to the plurality of conductive posts 195, respectively.

Referring to FIGS. 1, 3A, and 3B, the upper and lower semiconductor chips 110 and 120 may include semiconductor substrates 111 and 121, respectively. The active surfaces 110A and 120A of the semiconductor substrates 111 and 121 may include a plurality of active/passive elements (e.g., transistors), and wiring structures 113 and 123 connecting the plurality of active/passive elements to the connection pads 115 and 125 may be on the active surfaces 110A and 120A of the semiconductor substrates 111 and 121. Each of the wiring structures 113 and 123 may include an insulating layer and multiple wiring layers implemented in the insulating layer.

In some embodiments, the upper and lower semiconductor chips 110 and 120 may be a processor chip or a memory chip. For example, the upper semiconductor chip 110 may include a microprocessor, a graphics processor, a signal processor, a network processor, a chipset, an audio codec, a video codec, an application processor, or a system on chip but is not limited thereto. For example, the upper semiconductor chip 110 may be a control chip for driving a memory device.

In some embodiments, the lower semiconductor chip 120 may be a volatile memory chip and/or a nonvolatile memory chip. For example, the volatile memory chip may include dynamic random access memory (DRAM), static RAM (SRAM), zero capacitor RAM (ZRAM), or twin transistor RAM (TTRAM). In addition, the nonvolatile memory chip may include, for example, flash memory, magnetic RAM (MRAM), spin-transfer torque MRAM (STT-RAM), ferroelectric RAM (FRAM), phase change RAM (PRAM), resistive RAM (RRAM), nanotube RRAM, polymer RAM, nano floating gate memory, holographic memory, molecular electronics memory, or insulator resistance change memory.

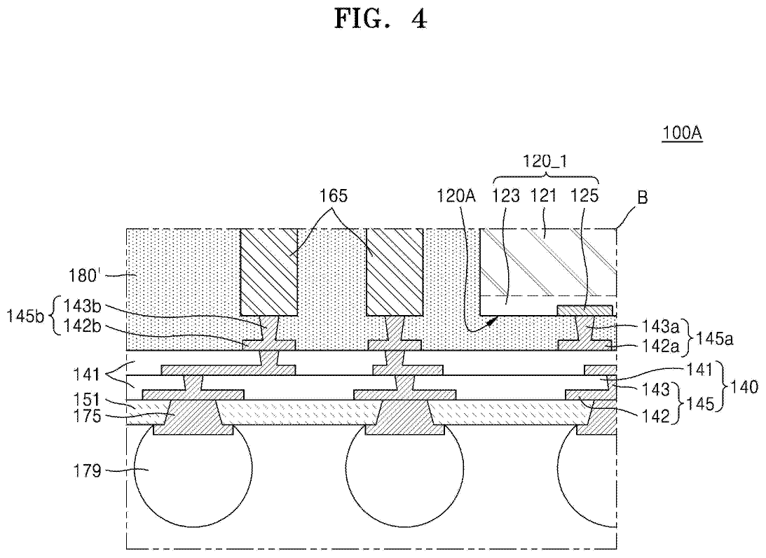

FIG. 4 is a partial magnified view of a semiconductor package 100A according to some embodiments and may be understood as a magnified view of the portion B of the semiconductor package 100 shown in FIG. 1, like FIG. 3B.

Referring to FIG. 4, it may be understood that the semiconductor package 100A has a similar structure as that of the semiconductor package 100 shown in FIGS. 1, 2, 3A, and 3B except for a connection structure of the lower redistribution layer 145 with the first lower semiconductor chip 120_1 and vertical interconnectors 165. Therefore, the description of the semiconductor package 100 shown in FIGS. 1, 2, 3A, and 3B may be combined with a description of the semiconductor package 100A shown in FIG. 4 unless there is a particularly opposite description thereto.

The lower redistribution layer 145 may be connected to the connection pads 125 of the first lower semiconductor chip 120_1 and the vertical interconnectors 165 through first and second vias 143a and 143b, respectively. For example, the first and second vias 143a and 143b may contact the connection pads 125 and the vertical interconnectors 165, respectively. The first and second vias 143a and 143b may constitute first-level redistribution layers 145a and 145b together with first and second redistribution patterns 142a and 142b, respectively. A mold portion 180′ employed in the present embodiment may have openings connected to the connection pads 125 and the vertical interconnectors 165, and the first-level redistribution layers 145a and 145b may be in the mold portion 180′ and connected to the connection pads 125 and the vertical interconnectors 165 through the openings of the mold portion 180′. For example, the mold portion 180′ may include a photosensitive insulating material, such as a PID. As described above, the lower redistribution layer 145 on the mold portion 180 or 180′ may be connected to the connection pads 125 of the lower semiconductor chip 120 and the vertical interconnectors 165 in various methods.

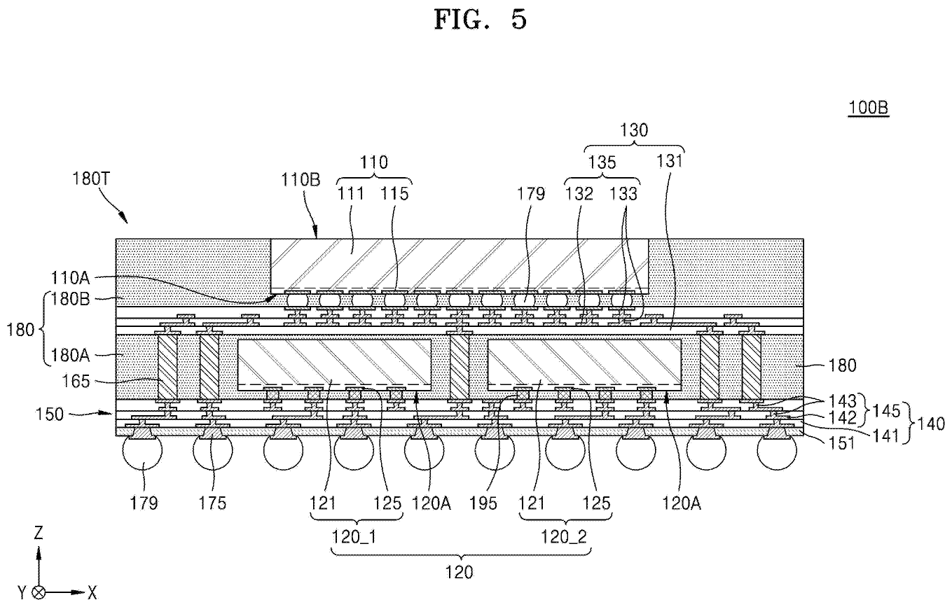

FIG. 5 is a side cross-sectional view of a semiconductor package 100B according to some embodiments.

Referring to FIG. 5, it may be understood that the semiconductor package 100B has a similar structure as those of the semiconductor packages 100 and 100A shown in FIGS. 1 to 4 except that an upper surface 180T of the mold portion 180 is coplanar with the inactive surface 110B, i.e., the uppermost surface, of the upper semiconductor chip 110. Therefore, the description of the semiconductor packages 100 and 100A shown in FIGS. 1 to 4 may be combined with a description of the semiconductor package 100B shown in FIG. 5 unless there is a particularly opposite description thereto.

In the present embodiment, the upper semiconductor chip 110 may be exposed from the upper surface 180T of the mold portion 180, i.e., the upper surface of the second portion 180B of the mold portion 180.

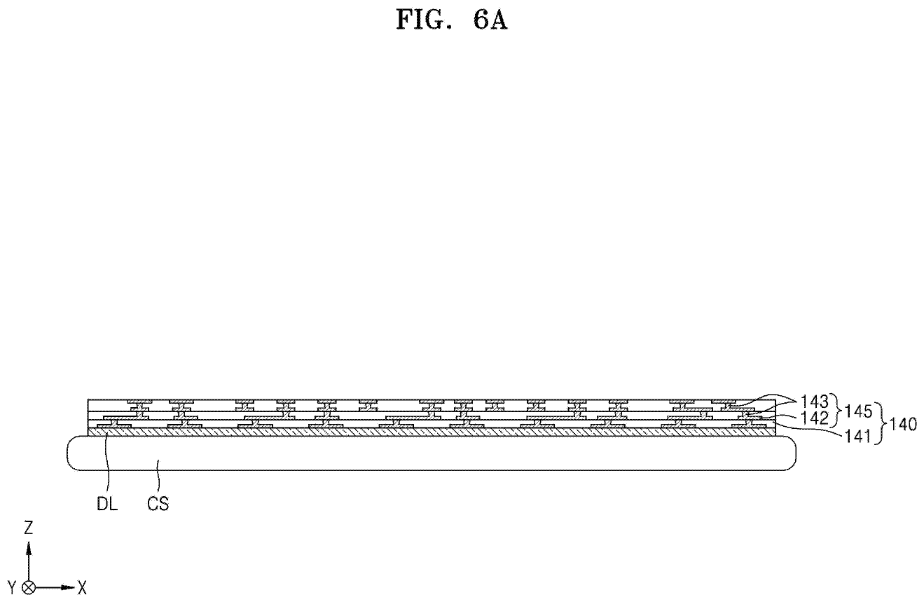

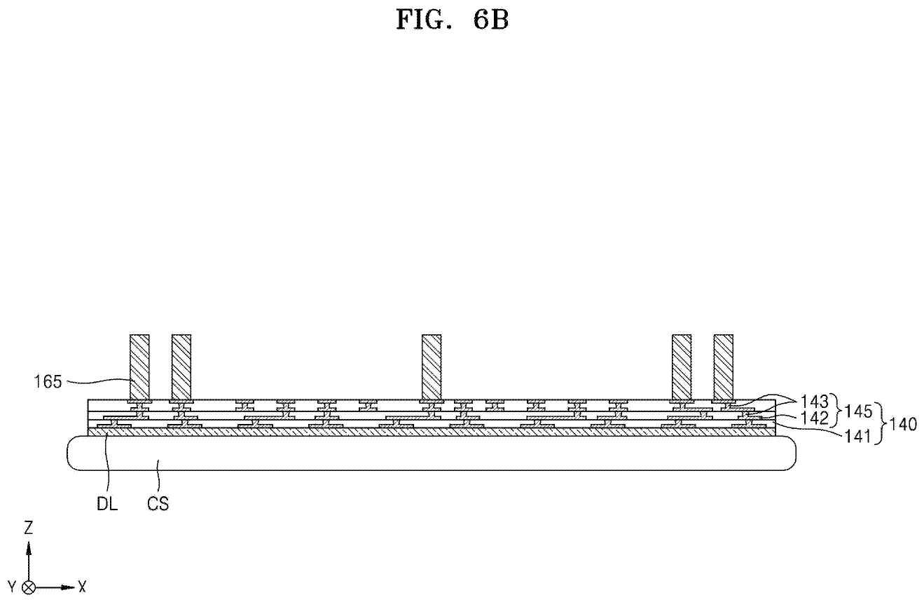

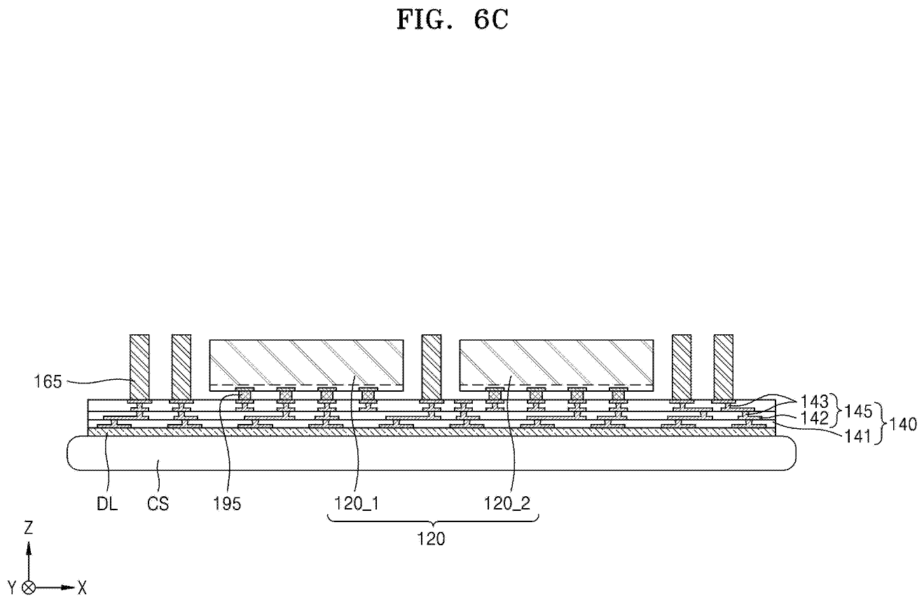

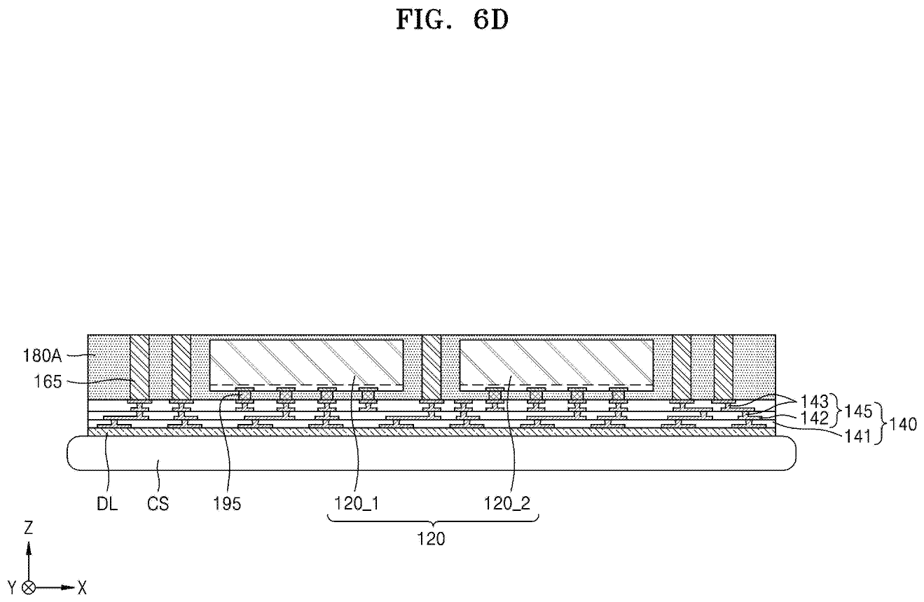

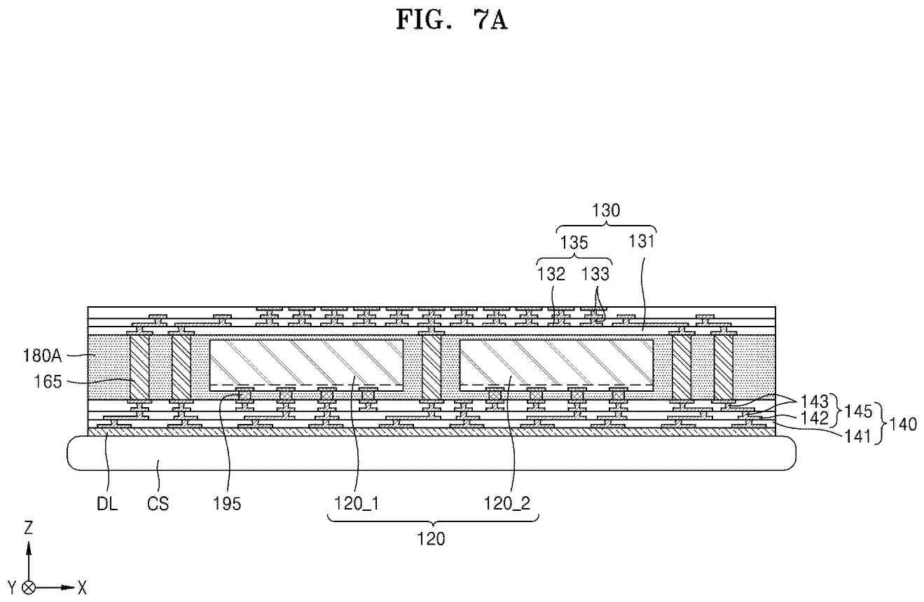

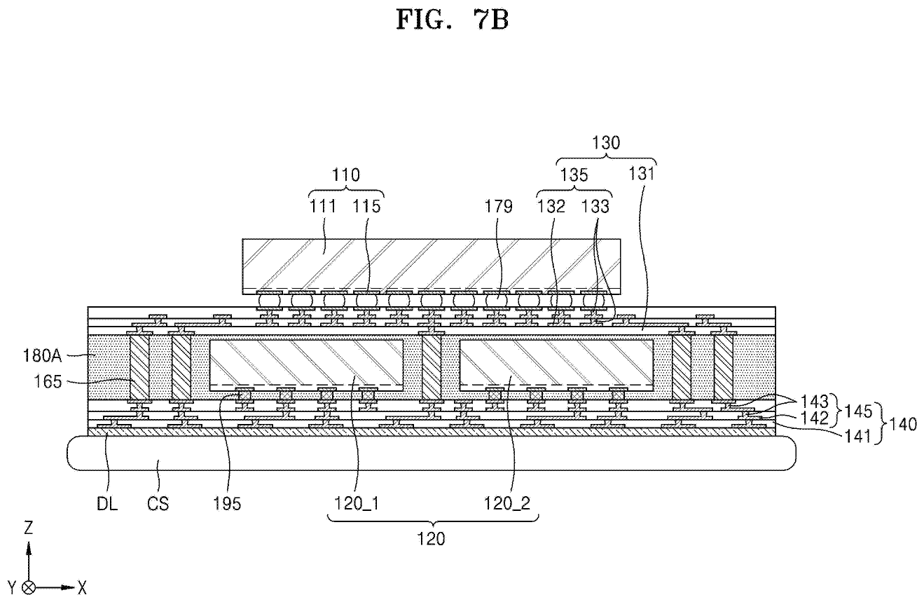

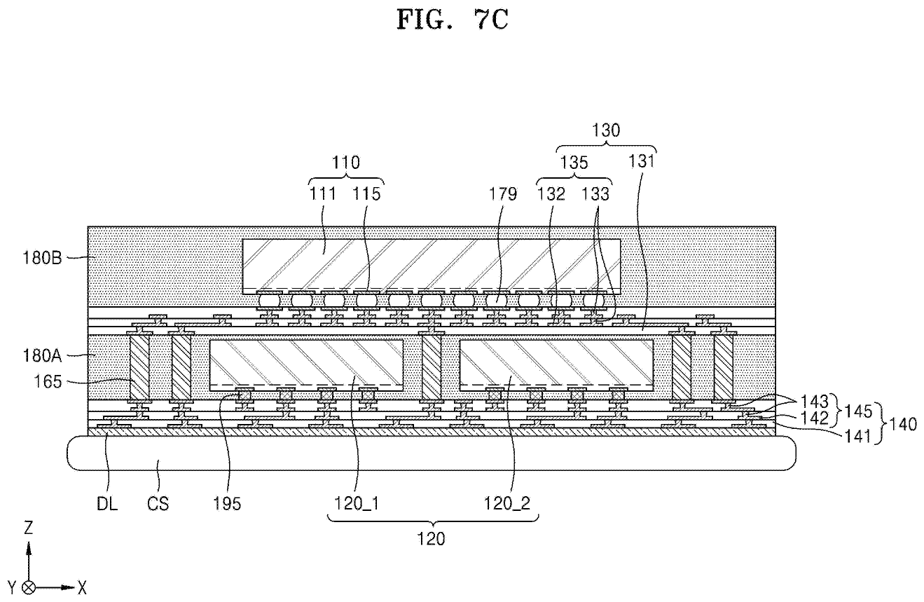

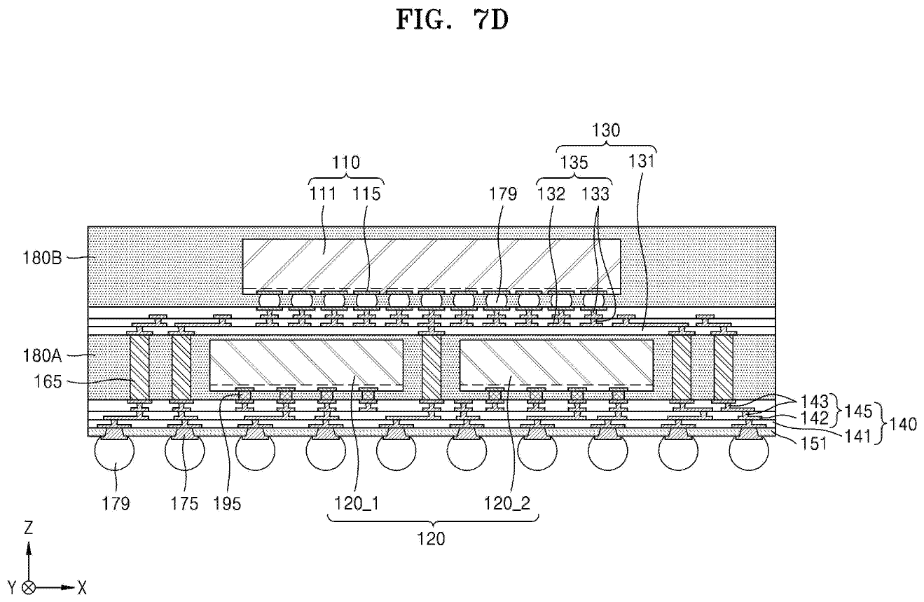

FIGS. 6A to 6D and 7A to 7D are cross-sectional views of main processes to describe some processes of a method of manufacturing the semiconductor package 100, according to some embodiments.

Referring to FIG. 6A, an adhesive insulating layer DL may be attached to a carrier substrate CS, and the second connection member 140 including the lower redistribution layer 145 and the plurality of insulating layers 141 may be formed on the adhesive insulating layer DL. The lower redistribution layer 145 may include the redistribution patterns 142 and the plurality of vias 143.

The carrier substrate CS may include, for example, glass, silicon, or Al oxide. The adhesive insulating layer DL may include a material fixable to the second connection member 140. The adhesive insulating layer DL may include, for example, adhesive tape of which the adhesive strength is weakened by annealing or laser irradiation.

In some embodiments, the second connection member 140 may be formed on the adhesive insulating layer DL through a plating or deposition process.

As shown in FIGS. 6A to 7D, in the method of manufacturing the semiconductor package 100, according to the inventive concepts, each of vias 133 and 143 may have a horizontal width increasing away from the carrier substrate CS. However, the vias 133 and 143 are not limited thereto and may have different shapes.

Next, referring to FIG. 6B, the plurality of vertical interconnectors 165 may be formed on the second connection member 140.

The plurality of vertical interconnectors 165 may be formed to be higher than the mounting height of second semiconductor chips (see 120_1 and 120_2 of FIG. 1) to be mounted in a subsequent process. In some embodiments, the plurality of vertical interconnectors 165 may be formed through a plating process using a photoresist. For example, a seed layer (e.g., a Ti layer) may be formed on the second connection member 140, then a photoresist may be formed on the seed layer, and openings exposing regions in which the plurality of vertical interconnectors 165 are to be formed may be formed in the photoresist. Contact regions of the second redistribution layer 145 may be exposed through the openings. Next, the plurality of vertical interconnectors 165 having a post structure may be formed in regions exposed by the openings through a plating process. By stripping the photoresist, as shown in FIG. 6B, the plurality of vertical interconnectors 165 electrically connected to the second redistribution layer 145 may be formed.

Referring to FIG. 6C, a plurality of second semiconductor chips 120_1 and 120_2 may be individually mounted on the second connection member 140. For example, the plurality of second semiconductor chips 120_1 and 120_2 may be connected to the second redistribution layer 145 through a plurality of conductive posts 195.

In some embodiments, the plurality of second semiconductor chips 120_1 and 120_2 may be memory chips. The plurality of second semiconductor chips 120_1 and 120_2 may be volatile memory chips and/or nonvolatile memory chips.

Referring to FIG. 6D, a mold portion 180A may be formed on (e.g., may be formed to cover) the second connection member 140, the plurality of vertical interconnectors 165, and the plurality of second semiconductor chips 120_1 and 120_2. In some embodiments, the mold portion 180A may be formed thick to completely cover the second connection member 140, the plurality of vertical interconnectors 165, and the plurality of second semiconductor chips 120_1 and 120_2 and then an upper portion of the mold portion 180A may be removed through grinding so as to expose the upper surfaces of the plurality of vertical interconnectors 165 to the outside.

In some embodiments, the upper surface of the mold portion 180A may be coplanar with the upper surfaces of the plurality of vertical interconnectors 165.

The mold portion 180A may have portions filling spaces between the plurality of vertical interconnectors 165 and the plurality of second semiconductor chips 120_1 and 120_2. The mold portion 180A may be formed to surround the plurality of second semiconductor chips 120_1 and 120_2 and the plurality of vertical interconnectors 165. For example, the mold portion 180A may include an EMC or PID.

Referring to FIG. 7A, the first connection member 130 having the first redistribution layer 135 may be formed on the mold portion 180A and the plurality of vertical interconnectors 165.

The upper surfaces of the plurality of vertical interconnectors 165 may be in direct contact with the first redistribution layer 135. For example, the plurality of vertical interconnectors 165 may be electrically connected to the first redistribution layer 135. Accordingly, the first redistribution layer 135 may be electrically connected to the second redistribution layer 145 through the plurality of vertical interconnectors 165.

Like the second connection member 140, the first connection member 130 may include the plurality of insulating layers 131, and like the second redistribution layer 145, the first redistribution layer 135 may include a redistribution pattern 132 in each of the plurality of insulating layers 131 and the plurality of vias 133 each connecting adjacent redistribution patterns 132 to each other by penetrating (i.e., extending into) a corresponding insulating layer 131. For example, the insulating layer 131 may include a photosensitive insulating material, such as a PID resin, and the first redistribution layer 135 may include a conductive material, such as Cu, Al, Ag, Sn, Au, Ni, Pb, Ti, or an alloy thereof. At each level, a redistribution pattern 132 and a corresponding via 133 may be formed in an integrated structure through a plating process.

Referring to FIG. 7B, the first semiconductor chip 110 may be mounted on the first connection member 130.

In some embodiments, the first semiconductor chip 110 may be a processor chip. For example, the first semiconductor chip 110 may include a microprocessor, a graphics processor, a signal processor, a network processor, a chipset, an audio codec, a video codec, an application processor, a system on chip, or a control chip for driving a memory device. One of semiconductor chips included in the first semiconductor chip 110 may have the same area as at least one of the plurality of second semiconductor chips 120_1 and 120_2. However, the technical idea of the inventive concepts is not limited thereto and one of semiconductor chips included in the first semiconductor chip 110 may have an area different from that of at least one of the plurality of second semiconductor chips 120_1 and 120_2.

The first semiconductor chip 110 may be on the first redistribution layer 135 such that the active surface of the first semiconductor chip 110 faces the first redistribution layer 135 (e.g., see the active surface 110A of FIG. 1). In this case, the first semiconductor chip 110 may be electrically connected to the first redistribution layer 135 through the external connection metal 179 formed between the first semiconductor chip 110 and the first redistribution layer 135.

The first semiconductor chip 110 may be electrically connected to the external connection metal 179, the first redistribution layer 135, and vertical interconnectors 165. However, a method of disposing the first semiconductor chip 110 on the first redistribution layer 135 is not limited thereto. In some embodiments, a sawing process performed on a scribe lane between ones of a plurality of first semiconductor chips included in the first semiconductor chip 110 may be at least partially omitted such that one of the plurality of first semiconductor chips may be integrally connected to an adjacent one of the plurality of first semiconductor chips with the scribe lane therebetween on a same plane.

Referring to FIG. 7C, a mold portion 180B may be formed on (e.g., may be formed to cover) the first connection member 130 and the first semiconductor chip 110. In some embodiments, the mold portion 180B may be formed thick to completely cover the first connection member 130 and the first semiconductor chip 110 and then partially removed to a level higher than the upper surface of the first semiconductor chip 110 through a grinder (e.g., see the semiconductor package 100 of FIG. 1). Alternatively, the mold portion 180B may be formed by being removed to the same level as the upper surface of the first semiconductor chip 110 (e.g., see the semiconductor package 100B of FIG. 5). As used herein, the term “level” means a height in a vertical direction (e.g., the third direction Z) from an upper surface of a base substrate (e.g., see the base substrate 150 of FIG. 1) and/or from an upper surface of the second connection member 140. The mold portion 180B may include the same material as the mold portion 180A.

Referring to FIG. 7D, the carrier substrate CS may be removed, and the external connection metal 179 may be formed on the lower surface of the second redistribution layer 145. The external connection metal 179 may include, for example, a solder ball, a conductive bump, a conductive paste, a ball grid array (BGA), a land grid array (LGA), a pin grid array (PGA), or a combination thereof. The external connection metal 179 may be formed on the passivation layer 151 on the second connection member 140, and the UBM layer 175 may be connected to the second redistribution layer 145 through openings in the passivation layer 151.

While the inventive concepts have been particularly shown and described with reference to example embodiments thereof, it will be understood that various changes in form and details may be made therein without departing from the scope of the following claims.

What is claimed is:

1. A semiconductor package comprising:
a base substrate having a lower redistribution layer;
a lower semiconductor chip comprising a plurality of lower semiconductor chips having a first active surface and first connection pads on the first active surface, wherein the plurality of lower semiconductor chips are on the base substrate such that the first active surface faces an upper surface of the base substrate, and wherein each of the first connection pads is electrically connected to the lower redistribution layer;
an upper semiconductor chip having a second active surface and second connection pads on the second active surface, wherein the upper semiconductor chip is on the lower semiconductor chip such that the second active surface faces the lower semiconductor chip;
an intermediate connection member on the second active surface of the upper semiconductor chip and between the lower semiconductor chip and the upper semiconductor chip, the intermediate connection member having an upper redistribution layer electrically connected to each of the second connection pads;
a plurality of vertical interconnectors at least partially around the lower semiconductor chip on the base substrate and electrically connecting the lower redistribution layer to the upper redistribution layer; and
a mold portion on the base substrate and having a first portion at least partially surrounding the lower semiconductor chip and the plurality of vertical interconnectors and a second portion extending on the upper redistribution layer and side surfaces of the upper semiconductor chip,
wherein the upper semiconductor chip comprises a plurality of upper semiconductor chips, and one of the plurality of upper semiconductor chips is integrally connected to an adjacent one of the plurality of upper semiconductor chips with a scribe lane therebetween on a same plane.

2. The semiconductor package of claim 1, wherein the second portion of the mold portion surrounds all side surfaces of the upper semiconductor chip and the intermediate connection member.

3. The semiconductor package of claim 1, wherein the upper semiconductor chip further comprises a second inactive surface opposite to the second active surface, and
wherein a height from the upper surface of the base substrate to the second inactive surface of the upper semiconductor chip is less than a height from the upper surface of the base substrate to an upper surface of the second portion of the mold portion.

4. The semiconductor package of claim 1, wherein the intermediate connection member has a greater area than an active surface of the one of the plurality of upper semiconductor chips and an active surface of the adjacent one of the plurality of upper semiconductor chips.

5. The semiconductor package of claim 1, wherein the plurality of lower semiconductor chips are separated from each other on the base substrate.

6. The semiconductor package of claim 1, wherein at least some of the plurality of vertical interconnectors are between ones of the plurality of lower semiconductor chips.

7. The semiconductor package of claim 1, wherein a horizontal distance between ones of the plurality of lower semiconductor chips is different from a horizontal distance between ones of the plurality of upper semiconductor chips.

8. The semiconductor package of claim 1, wherein the base substrate has a greater area than the intermediate connection member.

9. The semiconductor package of claim 1, wherein the base substrate has side surfaces that are substantially flat and coplanar with side surfaces of the mold portion.

10. The semiconductor package of claim 1, wherein the upper redistribution layer comprises a plurality of redistribution patterns and a plurality of vias electrically connected to the plurality of redistribution patterns, and
wherein at least some of the plurality of vias are electrically connected to the second connection pads.

11. The semiconductor package of claim 1, further comprising a plurality of conductive posts on lower surfaces of the first connection pads, respectively,
wherein the mold portion has a third portion covering the first active surface of the lower semiconductor chip,
wherein the plurality of conductive posts extend into the third portion of the mold portion, and
wherein the lower redistribution layer is electrically connected to the plurality of conductive posts.

12. The semiconductor package of claim 1, wherein the lower redistribution layer comprises a plurality of redistribution patterns and a plurality of vias electrically connected to the plurality of redistribution patterns, and
wherein the plurality of vias comprise vias that contact the first connection pads.

13. The semiconductor package of claim 1, further comprising an external connection metal on the second active surface of the upper semiconductor chip.

14. The semiconductor package of claim 1, wherein the lower semiconductor chip comprises a memory chip, and the upper semiconductor chip comprises a processor chip.

15. A semiconductor package comprising:
a plurality of first semiconductor chips having a first surface, first connection pads on the first surface, and a second surface opposite to the first surface;
a first connection member on the first surface of at least one of the plurality of first semiconductor chips and having a first redistribution layer electrically connected to the first connection pads;
a plurality of second semiconductor chips having a third surface and second connection pads on the third surface;
a second connection member on the third surface of at least one of the plurality of second semiconductor chips and having a second redistribution layer electrically connected to the second connection pads;
a plurality of vertical interconnectors on the second connection member, at least partially around the plurality of second semiconductor chips, and electrically connecting the first redistribution layer to the second redistribution layer;
a mold portion on the second connection member, at least partially surrounding the plurality of second semiconductor chips and the plurality of vertical interconnectors, and extending on the first connection member and side surfaces of the plurality of first semiconductor chips; and
a scribe lane between ones of the plurality of first semiconductor chips.

16. The semiconductor package of claim 15, wherein the ones of the plurality of first semiconductor chips are at opposing sides of the scribe lane and are integrally connected on a same plane.

17. The semiconductor package of claim 15, wherein a distance between the ones of the plurality of first semiconductor chips is different from a distance between ones of the plurality of second semiconductor chips.

18. The semiconductor package of claim 15, wherein a height from an upper surface of the second connection member to the second surface of the at least one of the plurality of first semiconductor chips is less than a height from the upper surface of the second connection member to an uppermost surface of the mold portion.

19. A semiconductor package comprising:
a base substrate having a lower redistribution layer;
a plurality of lower semiconductor chips having a first active surface, first connection pads on the first active surface, and a first inactive surface opposite to the first active surface, wherein the plurality of lower semiconductor chips are separated from each other and are on the base substrate such that the first active surface faces the base substrate;
a plurality of upper semiconductor chips having a second active surface, second connection pads on the second active surface, and a second inactive surface opposite to the second active surface, wherein the plurality of upper semiconductor chips have a greater area than the plurality of lower semiconductor chips and are on the plurality of lower semiconductor chips such that the second active surface faces at least one of the plurality of lower semiconductor chips, and wherein ones of the plurality of upper semiconductor chips are on a same plane with a scribe lane therebetween;
an intermediate connection member on the second active surface of at least one of the plurality of upper semiconductor chips and between the at least one of the plurality of lower semiconductor chips and the at least one of the plurality of upper semiconductor chips, the intermediate connection member having an upper redistribution layer electrically connected to each of the second connection pads;
a plurality of first vertical interconnectors at least partially around the plurality of lower semiconductor chips on the base substrate and electrically connecting the lower redistribution layer to the upper redistribution layer;
a plurality of second vertical interconnectors between ones of the plurality of lower semiconductor chips, below the plurality of upper semiconductor chips, and electrically connecting the upper redistribution layer to the lower redistribution layer; and
a mold portion on the base substrate, at least partially surrounding the lower semiconductor chip and the plurality of first and second vertical interconnectors, and extending on the upper redistribution layer and side surfaces of the plurality of upper semiconductor chips,
wherein a height from an upper surface of the base substrate to an uppermost surface of the mold portion is greater than a height from the upper surface of the base substrate to the second inactive surface of the at least one of the plurality of upper semiconductor chips.

20. The semiconductor package of claim 19, wherein a distance between the ones of the plurality of lower semiconductor chips is different from a distance between the ones of the plurality of upper semiconductor chips.
